(19) United States
(12) Patent Application Publication
(10) Pub. No.: US 2005/0041458 A1
(43) Pub. Date: Feb. 24, 2005

(54) Molecular electronic component used to construct nanoelectronic circuits, molecular electronic component, electronic circuit and method for producing the same

(76) Inventors: Harald Lossau, Munchen (DE); Gerhard Hartwich, Munchen (DE)

Correspondence Address: Aaron Wininger;Squire Sanders & Dempsey, 600 Hansen Way, Palo Alto, CA, 94304, US

(21) Appl. No.: 10/494,745

(22) PCT Filed: Nov. 8, 2002
(86) PCT No.: PCT/DE02/04144

(30) Foreign Application Priority Data
Nov. 9, 2001 (DE) 101-55-054.5

(51) Int. Cl. G11C 11/00; G11C 13/00

(52) U.S. Cl. 365/151

(57) ABSTRACT

A molecular electronic device for constructing nanoelectronic circuits comprises a redox-active moiety having an electron donor (D) and an electron acceptor (A), the electron donor and the electron acceptor (A) having a respective contact spot (K1, K2) for forming connections with other devices, and the contact spots (K1, K2) facilitating charge transport to the device and away from the device. In particular, the respective contact spot (K1, K2) of electron donor (D) and electron acceptor (A) is a permanent contact spot for mediating the charge transport across a permanent chemical bond, the contact spot respectively comprising one of the binding partners of the chemical bond. Multiple such devices can be combined via the contact spots to form a module or an electronic circuit.

The present invention relates to the field of devices of molecular dimensions for constructing nanoelectronic circuits, and relates especially to a molecular electronic device, a molecular electronic module comprising molecular devices, and an electronic circuit having such molecular devices or modules, and a production method for such an electronic circuit.

The technological development of microelectronics is documented by the SIA (Semiconductor Industry Association) (SIA roadmap: www.sematech.org/public/publications). Therein, the four-fold increase in the complexity of electronic chips every three years that has been observed since 1970 (Moore's Law) is forecast for the next two decades, as well. Semiconductor technology will increasingly reach its physical limits, especially since the necessary minimum feature sizes will soon reach molecular dimensions. Against this backdrop, work is increasing to realize electronic devices having dimensions of a few nanometers—so-called nanoelectronic devices.

Patent specification DE 198 58 759 describes a circuit arrangement allowing nanoelectronic devices to be combined with a CMOS device in a semiconductor substrate. However, the nanoelectronic devices themselves are not treated in this specification.

Known nanoelectronic devices include transistors consisting of semiconductor structures of a few nanometers in size. F. G. Pikus et al. (Nanoscale field-effect transistors: An ultimate size analysis, Appl. Phys. Lett. 71 (25) (1997) 3661), for example, describes a nanoelectronic CMOS device. What is addressed here are miniaturized “classical” devices based on semiconductor crystals and not devices constructed of individual molecules.

U.S. Pat. No. 4,539,507, U.S. Pat. No. 5,247,190, and DE 197 35 653 present polymers as electroluminescing substances. Layers of the active materials that can be employed for producing organic light-emitting diodes (OLED) are discussed. These specifications do not describe individual molecules as individually contactable units.

Since the discovery of fullerenes and the discovery of the supraconductivity of n-doped fullerenes, considerable research activity has occurred with these closed carbon molecules (Cₙ molecules with n>60). Fullerenes can be pulled as crystals or deposited as epitaxial layers. These so-called fullerites are treated in DE 198 22 333 and can be doped to produce electronic devices.

WO 98/39250 likewise discusses carbon nanotubes consisting of fullerenes and having a diameter of 0.6 to 100 nm and a length of 5 to 1000 nm, that are suitable as molecular electrical conductors for quantum effect components, but also as antennas for optical frequencies, STM and AFM tips. A memory cell is described having one nanobit (1.38 nm in diameter, 10-50 nm in length), that is written and read via molecular “wires” that are just as small. Here, the bit is stored due to the bistable position of a small molecule within a nanotube. Here, carbon nanotubes likewise serve as molecular wires.

Molecular conductors are known in many embodiments. S. Kagoshima et al. (One-dimensional Conductors, Springer Verlag 1988) describes, in addition to conductive organic crystals such as fluoranthene hexafluorophoshate, perylene hexafluorophoshate, and other radical cation salts of the arenes, especially conductive linear polymers. The latter comprise polyacetylenes (CH)ₓ, carbynes Cₓ, sulfur-nitrogen polymers (SN)ₓ, polypyrroles, and phenylacetylenes (=phenylethynyls). Oligo-phenylethynyls were employed by S. Creager et al. (J. Am. Chem. Soc. 121 (1999) 1059-1064) as molecular wires between gold electrodes and ferrocenes. In J. D. Holmes (Science 287 (2000) 1471), nanowires made up of silicon crystals having diameters of 4 to 5 nm and lengths of a few micrometers are described.

P. Fromherz (Phys. Blatter 57 (2001) 43) mentions the electrical conductivity of nerve cells and describes functional contacts to them on semiconductor chips. Here, the possibility of constructing hybrid networks from nerve cells and microelectronics is announced.

From WO 00/31101 is known that also double-stranded nucleic acid oligomers, especially double-stranded DNA, can function as a molecular electrical conductor. The reaction center of photosynthesis (RC) is a further natural system in which currents flow at the molecular level. Based on the determined structure of the RCs of purple bacteria Rhodopseudomonas viridis (R. viridis) (J. Deisenhofer et al., Nature 318 (1985) 618) and Rhodobacter sphaeroides (Rb. sphaeroides) (C. Chang et al., FEBS Letters 205 (1986) 82), it was possible to determine the charge-separation mechanism in detail. Both reaction centers consist of pigments (a bacteriochlorophyll dimer P, two bacteriochlorophylls B_{A} and B_{B}, two bacteriopheophytins H_{A} and H_{B}, and two quinones Q and Q_{B}) that are embedded in a protein matrix. In the RC, upon irradiation with light, a photochemical reaction begins that results in an electron transfer and thus a transmembraneous electrochemical potential gradient that ultimately leads to the synthesis of energy-rich substances. The photoinduced charge separation spans an electron transfer chain from the excited state P* to B_{A}, H_{A}, and Q to the final electron acceptor Q_{B}. Following double reduction, the latter is protonated and detaches itself from the protein pocket as Q_{B}H₂. An electron transfer chain across multiple cytochromes follows, through which, among other things, the primary electron donor P is reduced again. In the case of Q_{B}-free RCs, the state P⁺Q⁻, which is stable for 100 ms, forms through the photoinduced charge separation within 200 ps with a quantum efficiency of 99.9%.

The reaction center of the thermophilic green bacterium Chloroflexus aurantiacus (Chl. aurantiacus) is characterized by temperature stability up to approximately 90° C., with—despite its pigment set differing from that of purple bacteria—the electron transfer processes proceeding in a similar manner (R. Feick et al. in: Reaction Centers of Photosynthetic Bacteria, ed. M. E. Michel-Beyerle, Springer-Verlag 1990, p.181).

As an alternative to photosynthetic reaction centers, artificial donor-acceptor systems are produced and their electron transfer properties examined. H. A. Staab et al. (Chem. Ber. 127 (1994) 231; Ber. Bunsenges. Phys. Chem. 100 (1996) 2076; Chem. Phys. Lett. 209 (1993) 251) produces and characterizes porphyrin-quinone cyclophanes as artificial photosynthetic reaction centers. They consist of at least one porphyrin as the donor (D), which is bridged with at least one quinone as the acceptor (A), and cross over to the charge-separated state D⁺A⁻ upon optical excitation.

WO 00/19550 describes artificial photosynthetic reaction centers consisting of a triad made up of a porphyrin that is joined with a fullerene electron acceptor (A) and a carotenoid electron donor (D). This triad likewise crosses over to the charge-separated state D⁺A⁻ through photoinduced electron transfer. Since the lifetime of the latter depends strongly on an applied magnetic field, employment of this triad as a magnetically controlled optical or optoelectronic switch is suggested.

WO 00/42217 describes a nucleic acid oligomer to which a donor-acceptor complex, especially an RC or an artificial system, is attached. The construction is used to transfer charges to the oligomer and thus to electrochemically detect its hybridization state.

Self-organizing systems for producing nanostructured systems in which smaller molecular building blocks join together through self-organization to form larger units are illustrated in Whitesides et al. (Science 254 (1991) 1312). For this molecular nanotechnology, especially proteins and nucleic acids are suggested as building blocks (C. M. Niemeyer et al., Biospektrum 1 (1999) 31; K. E. Drexler et al., Proc. Natl. Acad. Sci. USA 78 (1981) 5275). J. Mbindyo et al. (Advanced Materials 13 (2001) 249) explains that gold nanowires can be self-organizingly arranged through modification with DNA.

M. Scheffier et al. describes tris-oligonucleotides, i.e. branched oligonucleotides, that are linked at the 3′-ends through a trifunctional linker, and points out a method that allows complex nanostructures to be constructed by means of self-organization.

This is where the present invention begins. The object of the present invention, as characterized in the claims, is to provide molecular electronic devices which allow to construct nanoelectronic circuits simply and effectively.

According to the present invention, this object is solved by the molecular electronic device according to claim 1 and claim 2, the molecular electronic module according to claim 23, and the electronic circuit according to claim 31. The present invention also provides a method for producing an electronic circuit according to claim 32 and 33. Further forms of the present invention are evident from the dependent claims.

According to the present invention, a molecular electronic device for constructing nanoelectronic circuits comprises a redox-active moiety having an electron donor and an electron acceptor, the electron donor and the electron acceptor having a respective contact spot for forming connections with other devices, and the contact spots facilitating charge transport to the device and away from the device. Here, the respective contact spot of electron donor and electron acceptor is a permanent contact spot for mediating the charge transport across a permanent chemical bond, the contact spot respectively comprising one of the binding partners of the chemical bond.

According to another form of the present invention, a molecular electronic device for constructing nanoelectronic circuits comprises a redox-active moiety having an electron donor and an electron acceptor, the electron donor and the electron acceptor having a respective contact spot for forming connections with other devices, and the contact spots facilitating charge transport to the device and away from the device. Here, a first one of the contact spots of electron donor and electron acceptor is a permanent contact spot for mediating the charge transport across a permanent chemical bond, the first contact spot comprising one of the binding partners of the chemical bond. A second one of the contact spots of electron donor and electron acceptor is a temporary contact spot for mediating the charge transport without permanently attaching a substance to the contact spot.

In the context of the present invention, a redox-active moiety is understood to be a moiety having at least one electron donor and at least one electron acceptor. The terms electron donor and electron acceptor here refer to redox-active substances. An electron donor is a molecule that can transfer an electron to an electron acceptor, directly or under the influence of certain external conditions. Conversely, an electron acceptor is a molecule that can take up an electron from an electron donor, directly or under the influence of certain external conditions. One such external condition is e.g. light absorption by the electron donor or acceptor of a photoinducibly redox-active moiety. Upon irradiation with light of a specific or any given wavelength, the electron donor D releases an electron to the/an electron acceptor A and a charge-separated state D⁺A⁻ forms, at least temporarily, from the oxidized donor and the reduced acceptor. A further such external condition may be the oxidation or reduction of the electron donor or acceptor of a chemically-inducibly redox-active moiety by an external oxidizing or reducing agent, so for example the transfer of an electron to the electron donor by a reducing agent, or the release of an electron by the electron acceptor to an oxidizing agent. The ability to act as an electron donor or acceptor is relative, i.e. a molecule that acts as an electron donor toward another molecule, directly or under the influence of certain external conditions, may also act as an electron acceptor toward that molecule under differing experimental conditions, or toward a third molecule under the same or differing experimental conditions. For further details and definitions, reference is made to the section “Photoinducibly and Chemically-Inducibly Redox-Active Moieties” of German laid-open print DE-A-199 26 457, the disclosure of which in that respect is incorporated into the present application.

The present invention is thus based on the idea of providing a complex made up of an electron donor and an electron acceptor with specific contact spots and of employing them as a molecular electronic device that can be connected with other devices via its contact spots, to construct extremely miniaturized electronic circuits.

By connecting two or more such devices via the contact spots, electronic modules are created that, based on their electrical function, can form for example a logic gate, a memory element, an amplifier, or a sensor.

By attaching a module, or multiple modules connected via linear binding molecules, to an electrically conducting surface, an electronic circuit is created that can be operated from outside via terminals on the conducting surface in the usual manner.

In a method of producing an electronic circuit, in solution
at least one first component part is added, a component part comprising a device of the above-mentioned type, a molecular electronic module of the above-mentioned type, or a conductive linear connection molecule,
at least one further component part is added, the first and the further component part having a respective permanent contact spot with corresponding binding partners, such that the first and the further component part connect in the solution at the corresponding contact spots,
the step of adding further components part is repeated,
   the further component part and one of the already connected component parts having a respective permanent contact spot with corresponding binding partners, such that the component parts connect in the solution at the corresponding contact spots until a number of predetermined component parts is connected, and
the connected component parts are applied to a conductive surface.

Alternatively, the circuit may be constructed starting from the conductive surface. There, a conductive surface is provided and, in solution,
a conductive surface is provided, on which in solution
at least one first component part is added and connected to the conductive surface,
at least one further component part is added,
   the first and the further component part having a respective permanent contact spot with mutually assigned binding partners, such that the first and the further component part connect in the solution at the corresponding contact spots,
the step of adding further component parts is repeated,
   the further component part and one of the already connected component parts having a respective permanent contact spot with corresponding binding partners, such that the component parts connect in the solution at the corresponding contact spots, until a number of predetermined component parts is connected.

The special advantage that results from a method according to the present invention is that the electronic circuit is produced self-organizingly, since the mutually corresponding binding partners of the assigned contact spots join together in the solution. Also, similar devices may be joined together simultaneously in large numbers.

Further advantageous forms, features, and details of the present invention are evident from the dependent claims, the description of the exemplary embodiments, and the drawings.

The present invention will be explained in further detail below by reference to exemplary embodiments in conjunction with the drawings. Only the elements that are essential to understanding the present invention are illustrated.

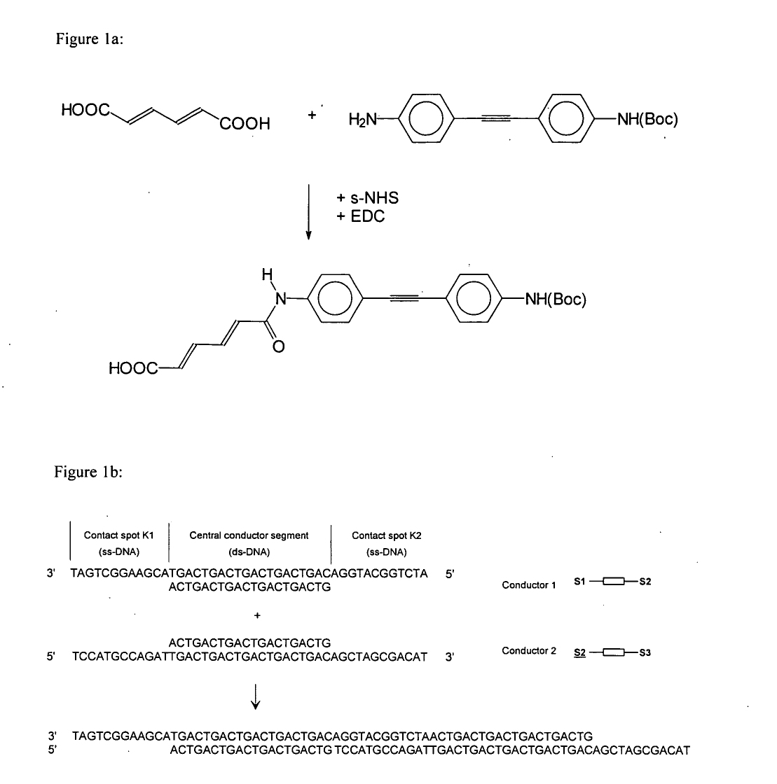

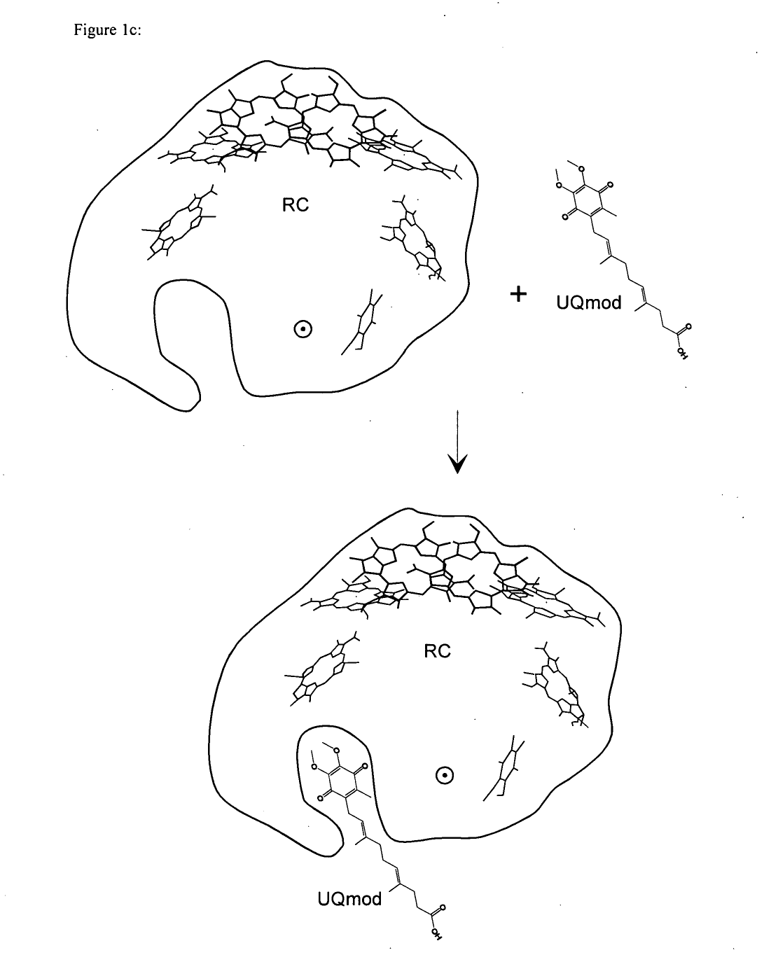

FIG. 1a Shows a connection between two molecular conductors (a functionalized polyacetylene and a phenylacetylene) via carboxy and amino contact spots. To avoid polymerization, instead of a second amino contact spot, a Boc-protected amino group is used (on the right-hand side of the image). To form the amide bond, N-hydroxysulfosuccinimide (s-NHS) and (3-dimethylaminopropyl)-carbodiimide (EDC) is added. After forming the connection, the protected amino group can be deprotected and employed as a further contact spot.

FIG. 1b Shows a specific connection between two molecular electrical conductors consisting of double-stranded nucleic acid oligomers (A,C,G,T), each having two contact spots (K1 and K2, and K2 and K3) consisting of single-stranded nucleic acid oligomers (sequences S1 and S2, and S2 and S3). For this purpose, the sequences S2 and S2 to be connection must be complementary to one another, which is expressed by the underscoring (S2). If the resistance of the double-stranded nucleic acid oligomer is not negligible compared with the remaining devices in a circuit (typically in the case of oligomers having more than 20 base pairs), the relevant device is referred to as a molecular resistor. A symbolic illustration of molecular resistors is shown on the right-hand side of the image.

FIG. 1c Shows a connection between a photosynthetic reaction center (RC) of Rb. sphaeroides and a molecular resistor via the quinone binding pocket. In this example, the molecular resistor is a modified ubiquinone (UQmod), consisting of a chain of isoprenoid units and two contact spots—a carboxy group and a quinone.

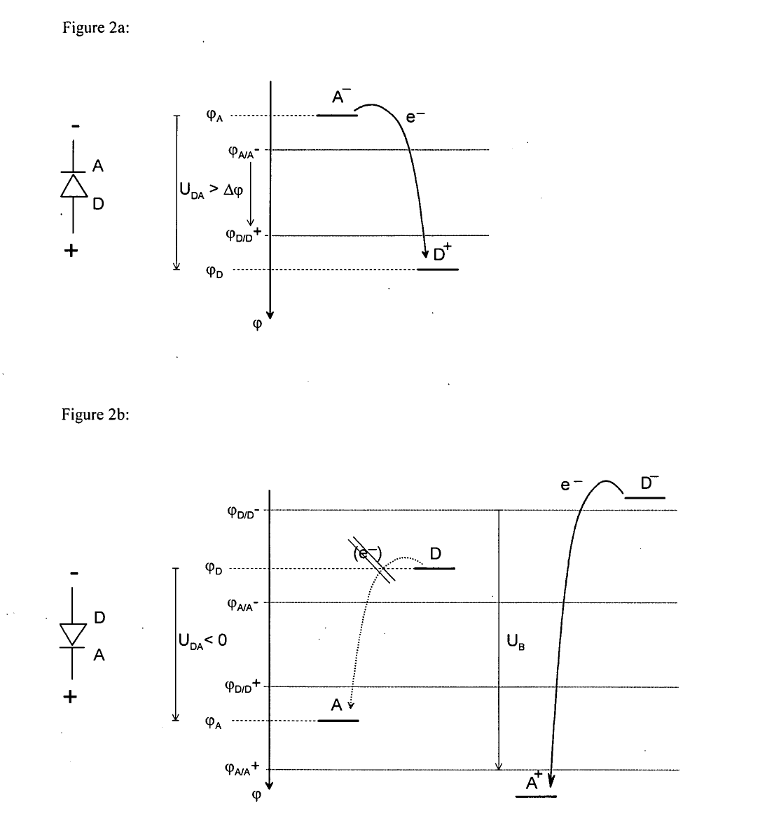

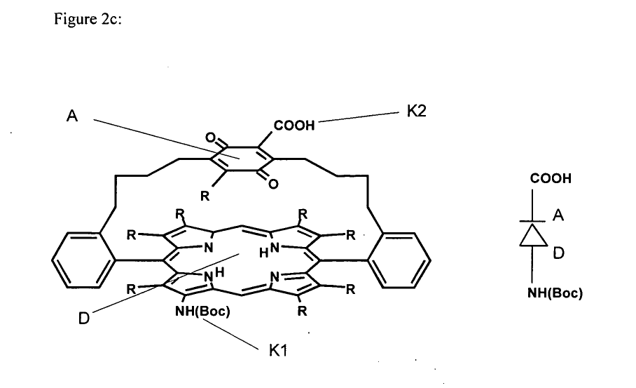

FIG. 2a Shows a molecular diode in forward direction (U_{DA}>Δφ).

FIG. 2b Shows a molecular diode in reverse direction (U_{DA}<0): The diode blocks in the voltage range 0>U_{DA}>U_{B} (left). If the diode voltage U_{DA} exceeds the breakdown voltage U_{B}, a current will also flow in reverse direction (right).

FIG. 2c Shows an example of a molecular diode consisting of a bridged porphyrin-quinone system and two contact spots K1 and K2. The porphyrin-quinone system consists of a donor D—a porphyrin—and an acceptor A—a quinone, which are double-bridged together. The donor is modified with a Boc-protected amino group—contact spot K1—and the acceptor with a carboxy group, as the contact spot K2. In the exemplary embodiment, the residues R represent methyl groups (standard) or hydrogen atoms, other alkyl groups, methoxy groups, halogens, and halogenated groups. A symbolic illustration of this diode is shown on the right-hand side of the image.

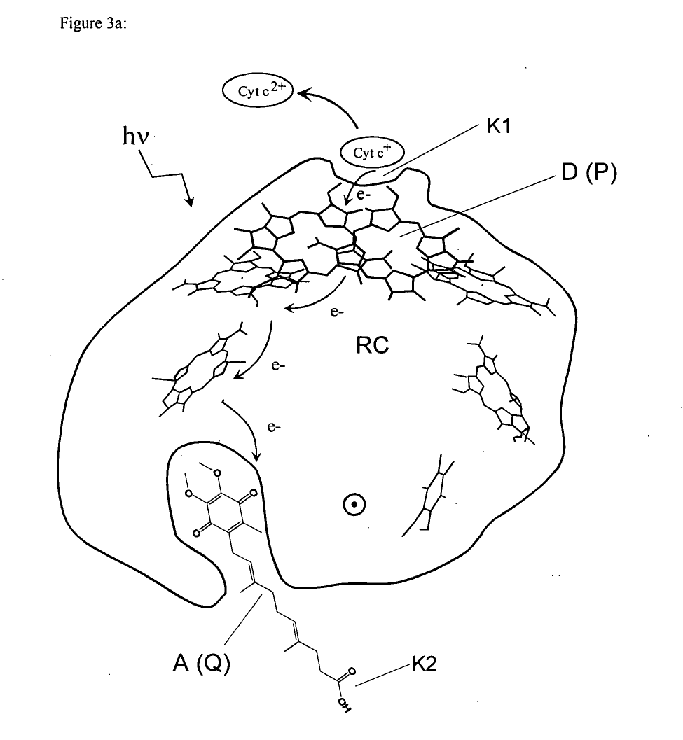

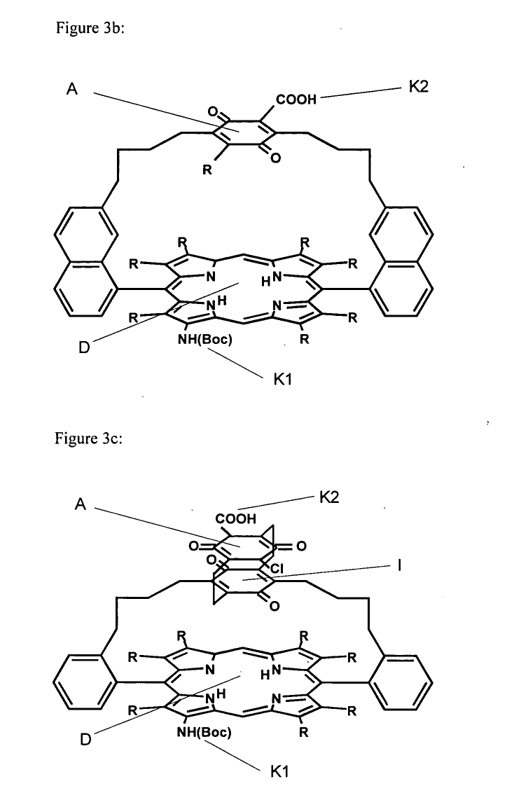

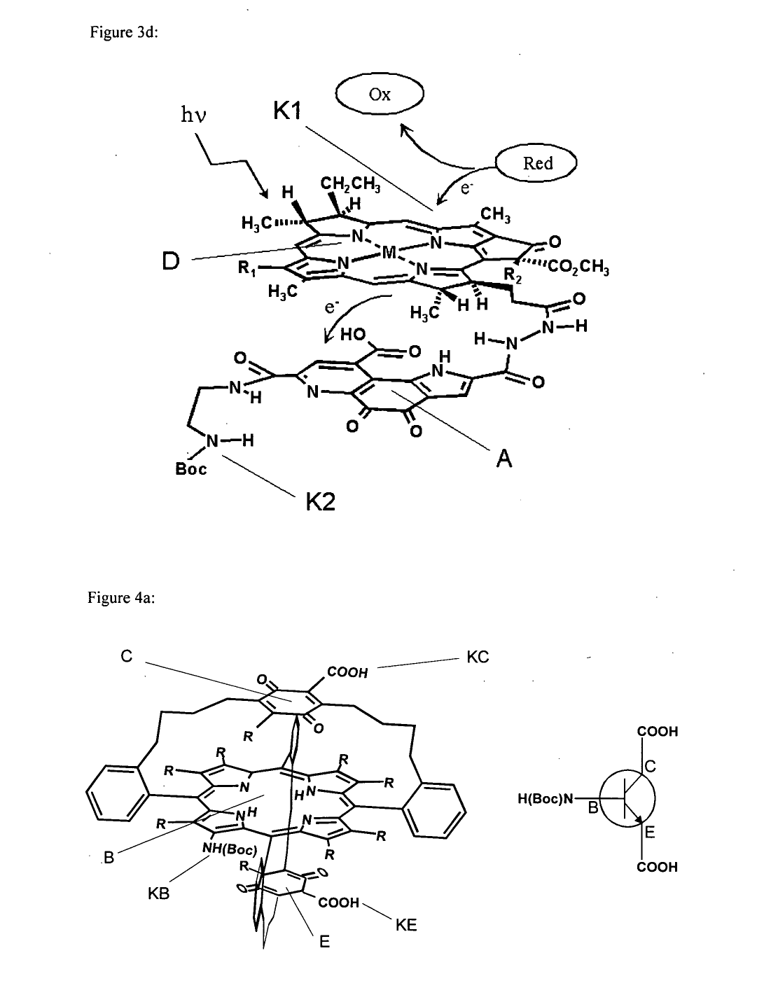

FIG. 3a Shows an example of a molecular photodiode consisting of a photosynthetic reaction center of Rb. sphaeroides (RC) and two contact spots, K1 and K2. The RC especially comprises a donor D—the primary donor or special pair (P)—and an acceptor A—the quinone Q equipped with a carboxy group. Upon optical excitation (hv), an electron transfer from P to Q occurs—the state P⁺Q⁻ forms. The positive charge on P can be tapped off via contact spot K1—a specific binding pocket for cytochrome c⁺ (Cyt c⁺). The electron on Q can be drawn off via the contact spot K2—the carboxy group of the modified quinone. Upon continued light-induced electron transfer, ultimately, a photocurrent flows.

FIG. 3b Shows an example of a molecular photodiode consisting of a bridged porphyrin-quinone system and two contact spots, K1 and K2. In contrast to the system in FIG. 2c, only the donor-acceptor spacing is increased through the employment of elongated bridge molecules.

FIG. 3c Shows an example of a molecular photodiode consisting of a double-bridged porphyrin-quinone-quinone system and two contact spots, K1 and K2. This exemplary embodiment comprises, in addition to an acceptor A that is substituted with contact spot K2 and a chlorine atom, an intermediate acceptor 1, across which the electron transfer is mediated from D to A.

FIG. 3d Shows an example of a molecular photodiode consisting of a bacteriochlorophyll derivative as the donor D and a pyrrolo-quinoline quinone as the acceptor A, which are bridged together, a permanent contact spot K2, and a temporary contact spot K1. Preferably, a zinc atom is employed as the central atom M of the bacteriochlorophyll derivative. The external reducing agent (Red) facilitates an electron transfer to the donor via the contact spot K1.

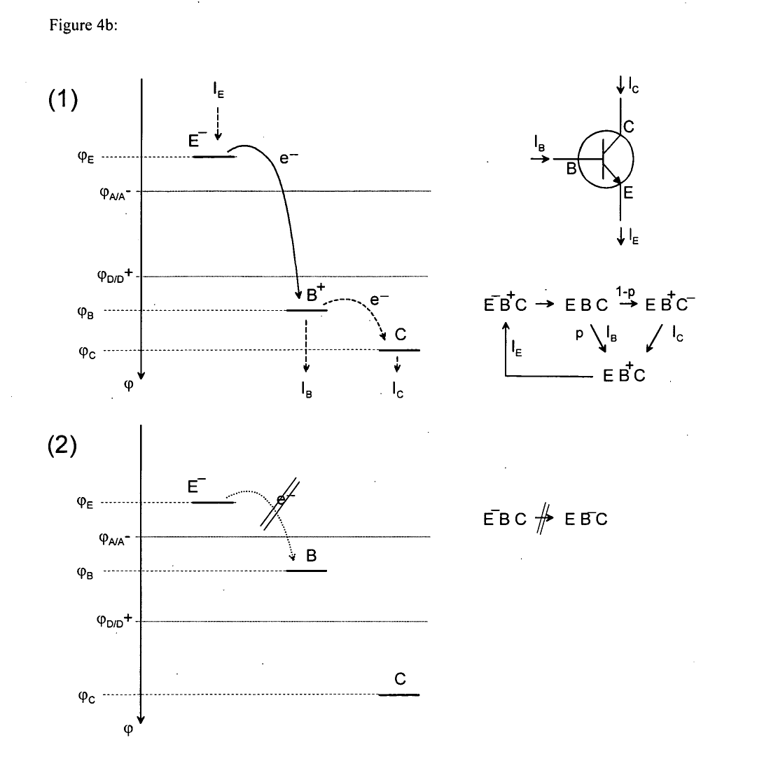

FIG. 4a Shows an example of a molecular NPN transistor based on a double-bridged quinone-porphyrin-quinone system. Collector C and emitter E both consist of a quinone having a respective contact spot, KC and KE, and are bridged with the base B—a porphyrin having the affiliated contact spot KB. A symbolic illustration of this transistor is shown on the right-hand side of the image.

FIG. 4b Shows an energy diagram and the operating principle of a molecular NPN transistor.

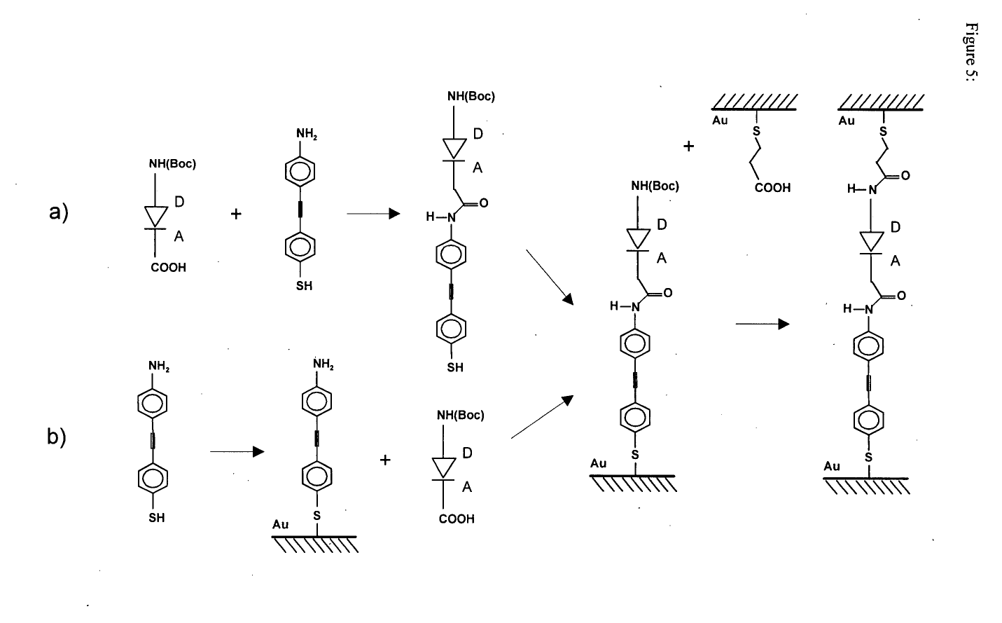

FIG. 5 Shows procedures for combining and contacting molecular electronic devices using the example of contacting a molecular diode via a molecular conductor on a gold surface: a) Construction of the system in solution and subsequent application on the surface. b) Successive construction of the system on the surface.

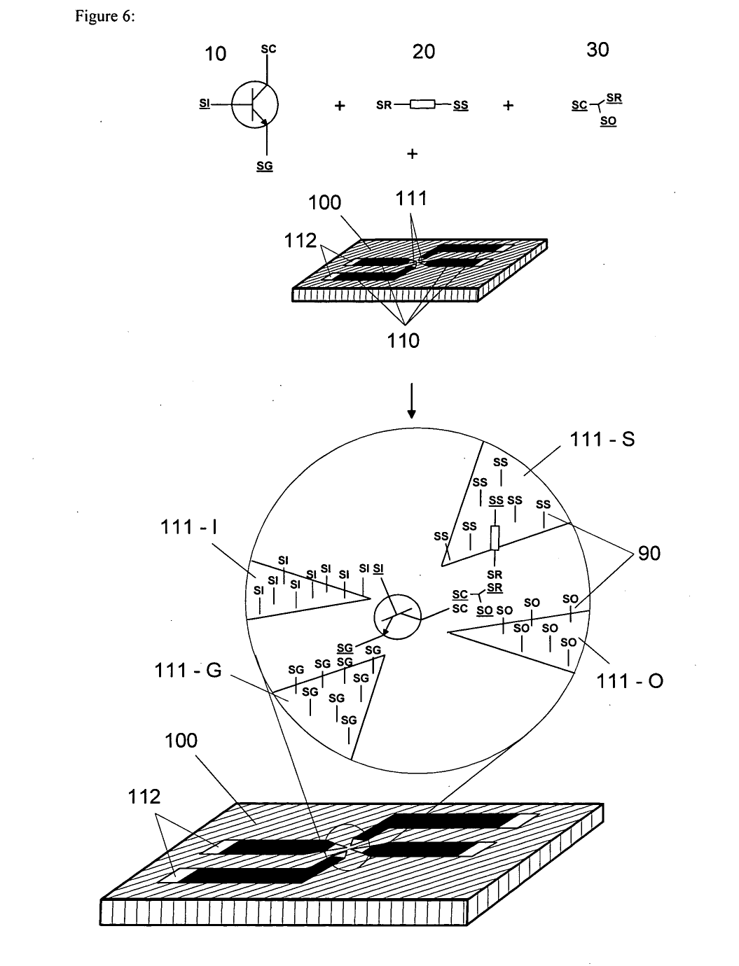

FIG. 6 Shows an example of a molecular inverter on a chip 100 having microcontacts 111 and macroscopic terminals 112, comprising a molecular transistor 10, a molecular resistor 20, and a connector 30.

The connection between the molecular devices is produced via contact spots made up of oligonucleotides.

1. Contact Spots, Molecular Electrical Conductors, and Resistors

First, contact spots, molecular electrical conductors, and resistors as used in the molecular devices of the present invention will be explained by way of example.

Examples of contact spots used in the present invention are:

a) Functional chemical groups, such as amino groups and coupling groups that can be specifically linked therewith (e.g. carboxy and hydroxyl groups, isothiocyanates, sulfonyl chlorides, aldhehydes, and activated esters, especially succinimidyl esters) or thiol groups and coupling groups that can be specifically linked therewith (e.g. alkyl halides, haloacetamides, maleimides, aziridines, and symmetrical disulfides) or hydroxyl groups and groups that can be specifically linked therewith (e.g. acyl azides, isocyanates, acyl nitriles, and acyl chlorides) or aldehydes, ketones, and groups that can be specifically linked therewith (e.g. hydrazines and aromatic amines).

Here, some of the functional chemical groups or the coupling groups can be equipped with protective groups for blocking certain connections. This allows two similar functional chemical groups to be used. First, one of the groups is protected and only the other is available for a reaction. Thus, only the desired bonds are formed and polymerization is avoided. Upon conclusion of the first reaction, the protective group can be removed for the second reaction, that is, the protected group can be deprotected.

FIG. 1a, for example, shows the connection between a carboxy contact spot of a molecular conductor and an amino contact spot group of another conductor. To avoid polymerization yet still permit a further connection, one of the two amino functions is equipped with a Boc protective group that can be deprotected following the connection of the two conductors in an acidic environment. Here, Boc stands for tert-butoxy carbonyl (—CO—O—C(CH₃)₃).

b) Single-stranded nucleic acid oligomers having a specific sequence. Preferably, DNA, RNA, or PNA oligonucleotides consisting of 5 to 30—in the example shown, 12—nucleotides are employed. In this way, a high number of different specific contact spots can be realized. FIG. 1b shows a specific connection between two molecular electrical conductors comprising double-stranded nucleic acid oligomers (A,C,G,T) having two contact spots each (K1 and K2, and K2 and K3) consisting of single-stranded nucleic acid oligomers (sequences S1 and S2 and S2 and S3). Here, A,G,C, and T stand for adenine, guanine, cytosine, and thymine, ss for single strand, and ds for double strand. For this purpose, the sequences to be linked, S2 and S2, must be complementary to one another, which is expressed by the underscoring (S2). If the resistance of the double-stranded nucleic acid oligomer is not negligible compared to the remaining devices in a circuit (typically in the case of oligomers having more than 20 base pairs), the appropriate device is referred to below as a molecular resistor. A symbolic illustration of molecular resistors is shown on the right-hand side of the image.

c) Specific binding sites at proteins and enzymes and their respective binding partners, for example, in the case of the photosynthetic reaction center (RC), the quinone binding pocket and the docking spot for the cytochrome c near the bacteriochlorophyll dimer, or the biotin binding pocket of the avidin. FIG. 1c, for example, shows the link between a photosynthetic reaction center of Rb. sphaeroides via the quinone binding pocket, and a molecular resistor, in this case, a modified ubiquinone. This consists of a chain of isoprenoid units having two terminal contact spots—at one end a carboxy group and at the other end a quinone. The latter fits perfectly into the binding pocket of the reaction center and forms therein a specific bond, just as the natural ubiquinone does.

The production of this ubiquinone having a reactive side group is described in patent application DE 100 57 415, the disclosure of which is incorporated into the present invention in this scope. To connect the RC and the modified ubiquinone, the natural ubiquinone is first extracted from the RC and thereafter, the RC having an empty binding pocket is reconstituted with the modified ubiquinone (Gunner, M. R., Robertson, D. E., Dutton, P. L., 1986, J. Phys. Chem., Vol. 90, 3783-3795, cf. WO 00/42217).

d) Photoactivatable crosslinkers, such as aryl azides and benzophenone derivatives.

e) Complex-forming ions, especially transition metal ions, and ligands associating therewith, such as oligopyrroles.

f) Temporary contact spots comprising a redox-active substance that is accessible to a further redox-active substance in solution, and that can exchange an electron therewith in a certain potential range. An example of this temporary contact spot is shown in FIG. 3d, and is described in greater detail below.

Within the context of the present invention, a distinction is made between permanent contact spots, which mediate electrical conductivity across a permanent chemical bond, and temporary contact spots, which mediate an electron transfer to dissolved redox-active substances without permanently binding these substances to the contact spot. In categories a), b), d), and e), the examples cited are permanent contact spots. This likewise applies to the biotin binding pocket and the quinone binding pocket of category c), which enter into a respective stable bond with a biotin or with a quinone. The docking spot for the cytochrome c binds same only temporarily and is thus to be counted among the temporary contact spots, as is category f).

Molecular Conductors

Conductive molecules or crystals equipped with contact spots at both ends are employed as molecular electrical conductors (wires). Examples of molecular wires comprise linear, unsaturated hydrocarbons, especially polyacetylenes (CH)ₓ (FIG. 1a, left), carbynes CX, sulfur-nitrogen polymers (SN)ₓ, polypyrroles, and phenylacetylenes (oligo-phenylethynyls, FIG. 1a, right), as well as double-stranded nucleic acid oligomers (e.g. FIG. 1b: DNA, RNA, or PNA), biological nerve cells, carbon nanotubes, silicon nanowires, and conductive organic crystals, such as fluoranthene hexafluorophosphate, perylene hexafluorophosphate, or other radical cation salts of the arenes.

Molecular Resistor

Each of the above-mentioned molecular wires can be employed as an electrical resistor if the length of the wire is chosen such that, at the given specific conductivity of the wire, the desired resistance is achieved (cf. FIG. 1b). Furthermore, resistors can be incorporated in the above-mentioned wires as follows:
a) For wires made up of unsaturated hydrocarbons, incorporating individual saturated carbon atoms increases electrical resistance.
b) For wires made up of double-stranded nucleic acid oligomers, incorporating base mismatches or sections of single-stranded nucleic acid oligomers increases resistance.
c) Incorporating foreign atoms (doping) changes the conductivity properties of carbon nanotubes.
   2. Diode

In a preferred embodiment, the donor-acceptor complex according to the present invention is employed as a rectifying diode—in analogy to a semiconductor diode, the donor corresponding to the p-doped semiconductor and the acceptor corresponding to the n-doped semiconductor. The working principle is explained with reference to FIG. 2.

Diode in Forward Direction (FIG. 2a):

To operate the diode according to the present invention in forward direction, a voltage U_{DA}>Δφ is applied to the donor-acceptor complex, in such a way that the donor D is at a potential φ_{D}>φ_{D/D+} and the acceptor A is at a potential φ_{A}<φ_{A/A-}. Here, φ_{D/D+} refers to the potential at which, at equilibrium, the neutral and the oxidized form of the donor are present with equal probability, φ_{A/A-} refers to the potential at which, at equilibrium, the neutral and the reduced form of the acceptor are present with equal probability, and Δφ=φ_{D/D+}−φ_{A/A-} is the difference between the two potentials.

Upon applying these potentials, the donor is oxidized via its electrical contact and the acceptor is reduced via its electrical contact, such that the charge-separated state D⁺A⁻ results. For application as a diode, the donor-acceptor complex is optimized according to the present invention in such a way that a rapid recombination of the state D⁺A⁻ is possible due to an electron transfer from A⁻ to D⁺. This can result, for example, by reducing the spacing between the donor and the acceptor, or selecting a donor and acceptor having suitable energy levels. The recombined state DA, in turn, is brought into the charge-separated state by a current flow across the electrical contacts. Due to continuous recombination, a current flows in forward direction as long as the voltage U_{DA} is applied.

Diode in Reverse Direction (FIG. 2b):

If a voltage U_{DA}<Δφ is applied to the diode, the donor-acceptor complex will remain in the ground state DA. If no energy is added from outside, e.g. through irradiation with light or through thermal energy, the generation rate, i.e. the rate of formation of the charge-separated state D⁺A⁻, is low (at T=0 it is zero). Charge separation does not occur, and thus no current flows—the diode blocks (FIG. 2b, on the left-hand side of the image).

Just as in the case of a semiconductor diode, a breakdown occurs in the case of the molecular diode if the reverse voltage is too high: if a reverse voltage with a larger absolute value than the breakdown voltage U_{B}=φ_{D/D-}−φ_{A/A+} is applied in such a way that the donor D is at a potential φ_{D}<φ_{D/D-} and the acceptor A is at a potential φ_{A}>φ_{A/A+}, the charge-separated state D⁻A⁺ forms. Here, φ_{D/D-} refers to the potential at which, at equilibrium, the neutral and the reduced form of the donor are present with equal probability, φ_{A/A+} the potential at which, at equilibrium, the neutral and the oxidized form of the acceptor are present with equal probability. The state D⁻A⁺ recombines immediately due to an internal electron transfer. The recombined state DA, in turn, is brought into the charge-separated state by a current flow across the electrical contacts. Due to continuous recombination, a current thus also flows in reverse direction as long as a reverse voltage is applied that is above the breakdown voltage U_{D} (FIG. 2b, on the right-hand side of the image).

Example of a Donor-Acceptor Complex That Can Be Employed as a Diode: An example of the molecular diode according to the present invention is based on a bridged porphyrin-quinone system (cf. Staab, H. A.; Krieger, C.; Anders, C.; Ruckemann, A., Chem. Ber. 1994, 127, 231-236) and additionally comprises a respective contact spot for the porphyrin as the donor D and the quinone as the acceptor A (FIG. 2c). The porphyrin-quinone system consists of a donor D—a porphyrin—and an acceptor A—a quinone, which are double-bridged together. The donor is modified with a Boc-protected amino group—the contact spot K1—and the acceptor with a carboxy group as the contact spot K2. In the exemplary embodiment, the residues R stand for methyl groups (standard) or hydrogen atoms, other alkyl groups, methoxy groups, halogens, and halogenated groups. A symbolic illustration of this diode is shown on the right-hand side of the illustration in FIG. 2c.

Here, the contact spot of the quinones consists of a carboxy group, via which it is possible to chemically bond to and electrically contact the acceptor (at the potential (PA). The contact spot of the porphyrin is a Boc-protected amino group for chemically binding and electrically contacting the donor (at the potential φ_{D}).

The oxidation and reduction potentials of these porphyrin-quinone systems are in the following order of magnitude (in dichloromethane, potentials relative to ferrocene): φ_{D/D+}=+0.3 V, φ_{A/A-}=−1.3 V, φ_{D/D-}˜−1.4 V, φ_{A/A+}≧0.4 V. This results in a threshold voltage of Δφ=1.6 V, above which the diode becomes conductive. For the reverse behavior, in addition to the diode itself, the properties of the environment or of the solvent must be considered. For example, an electrolytic current flows in water above a potential of +1.1 V. If environmental effects do not play a role, the breakdown voltage in reverse direction is approximately U_{B}=φ_{D/D-}−φA/A+≅−2.8 V.

The recombination time from the charge-separated state D+k was determined to be 40 PS (Pöllinger, F.; Musewald, C.; Heitele, H.; Michel-Beyerle, M. E.; Anders, C.; Futscher, M.; Voit, G.; Staab, H. A. Ber. Bunsenges. Phys. Chem. 1996, 100, 2076-2080). On the condition that the electron transfer across the contact spots does not determine speed, in other words, takes less than 40 PS, a maximum forward current of 4 nA per molecule results.

3. Photodiode

To employ the donor-acceptor complex according to the present invention as a photodiode, the complex is operated below the forward voltage, or in reverse direction, i.e., a voltage U_{DA}<Δφ is applied. The complex is optimized to the extent that, upon irradiation with electromagnetic radiation, especially light, the generation rate of the state D⁺A⁻ upon irradiation with light is as high as possible and the recombination rate is as low as possible. Furthermore, the photodiode is arranged such that external irradiation with light is possible, meaning especially that translucent materials are used for contacting and insulating the photodiode on the side facing the irradiation.

An example of a complex that is suitable as a photodiode and that has already been optimized by nature is the reaction center of photosynthesis (FIG. 3a). For example, the bacterial reaction centers (RC) of Rb. sphaeroides are excited, upon irradiation with light in the visible or near-infrared range, to efficient charge separation. Here, an electron transfer occurs from the primary donor D (P) across multiple intermediate steps to a quinone Q (or an acceptor A) within a time of 200 ps, resulting in the state P⁺Q⁻. (The RC possesses a further quinone binding pocket for a second quinone QB as the subsequent acceptor. However, this second quinone is bonded only very weakly, and is no longer present after the exchange of the first quinone Q (cf. section 1c).) Due to low recombination rates, the charge separation occurs with a quantum efficiency of more than 99%. Upon contact of the primary donor P and the quinone Q, the current flow across the contacts, caused by the light-driven charge separation, can be tapped off. It is especially possible to contact P through the natural cytochrome c (Cyt c), which can dock at the specific contact spot K1 at the RC. This molecule can give up an electron to the oxidized donor P⁺ by crossing over from the single positive-charge state Cyt c⁺ to the double positive-charge state Cyt c²⁺. Furthermore, it takes over the charge transport in solution up to a counterelectrode at which it can be rereduced. The quinone Q is modified with a carboxy group that serves as the second contact spot K2, via which the device can be attached to a gold electrode, for example.

Through a chemical modification (patent application DE 100 57 415, the disclosure of which is incorporated into the present application in this scope) the quinone can be provided with a carboxy group that serves as the second contact spot, via which a functional attachment is possible. The attachment can take place on a molecular conductor and/or on a conductive surface, for example on a gold surface coated with amino-terminated thiols.

An alternative way to provide the RC with contact spots consists in covalently attaching functional groups to the protein matrix of the RC in the direct environment of the donor or of the acceptor. In particular, the RC can be attached via a photoactivatable linker, for example benzophenone acid (BPA).

On the condition that the electron transfer across the contact spot K2 does not determine speed, the following photocurrents can be achieved for each molecule:

For the transfer of the first electron, the electron transfer time from Cyt c to the primary donor P determines speed. It is approximately 1 μs, resulting in a starting current of 0.2 pA. In the stationary case, given sufficient illumination of the RC (at least 3*10⁴ photons absorbed per second), the diffusion time of the Cyt c limits the current.

The diffusion time depends on the geometry of the overall arrangement and on the concentration of the Cyt c, and is about 300 μs (R. K. Clayton & W. R. William (ed.), The Photosynthetic Bacteria, Plenum Press 1978, p. 446). This results in a maximum stationary photocurrent of 0.5 fA per molecule.

If the molecular photodiodes are applied with a density of one molecule per (10 nm)² to a gold surface via the contact spot K2, the maximum stationary photocurrent density is 0.5 mA/cm².

Further examples of donor-acceptor systems that may be employed for molecular photodiodes are especially thermophilic reaction centers of Chloroflexus aurantiacus and artificial donor-acceptor systems such as the above-mentioned porphyrin-quinone system.

In the case of the porphyrin-quinone systems, given good contact, in other words, contact having high conductivity, very high photocurrents can be achieved for each molecule, since the electron transfer for forming the charge-separated state D+A lasts only a few picoseconds in the case of optical excitation. Due to the rapid recombination time of the system, the efficiency of this embodiment is limited. To reduce recombination as a competing process for draining the charge carrier across the contact spots, donor-acceptor systems having one or more intermediate states (as in the case of the above-described RC) or systems having rather large spacing between the donor and the acceptor can be employed. FIG. 3b shows such a porphyrin-quinone system, the donor-acceptor spacing of which is enlarged compared with the system shown in FIG. 2c, due to longer bridges (H.A. Staab, Achim Feurer, Claus Krieger, A. Sampath Kumar: Distance Dependence of Photoinduced Electron Transfer: Syntheses and Structures of Naphthalene-Spacered Porphyrin-Quinone Cyclophanes. Liebigs Ann. (1997), 2321-2336). A reduction of the recombination rate can likewise be achieved by employing a system comprising more than two redox-active substances, for example a system comprising a porphyrin and two quinones arranged in tandem (F. Pollinger, H. Heitele, M. E. Michel-Beyerle, M. Tercel, and H. A. Staab: Stacked Porphyrin-Quinone Triads as Models for the Primary Charge-Separation in Photosynthesis, Chem. Phys. Lett. 209 (1993) 251). The molecular photodiode based thereon comprises, in addition to this porphyrin-quinonel-quinone2 system, an amino group as the contact spot K1 at the porphyrin, and a carboxy group as the contact spot K2 at the quinone2 (FIG. 3c).

A further donor-acceptor system that can be used as the basis for a molecular photodiode is described in patent application WO 00/42217. FIG. 3d shows a corresponding exemplary embodiment consisting of a bacteriochlorophyll derivative (BChl) as the donor D and a pyrrolo-quinoline quinone (PQQ) as the acceptor A, which are bridged together, and the contact spots K1 and K2. Preferably, a zinc atom is employed as the central atom M of the bacteriochlorophyll derivative. In this system, the charge-separated state D⁺A⁻ forms through absorption of light of wavelength 770 nm. The contact spot K1 designates the outlying (at the top in FIG. 3d) side of the BChl, which is accessible to ferrocyanate as an external reducing agent (Red), thereby facilitating a specific rereduction of the oxidized donor D⁺ at the donor redox potential φ_{D/D+}=+0.4 V. The contact spot K2 at the acceptor, in turn, is a (Boc-protected) amino group, via which an electron can be drawn off from the reduced acceptor.

4. Solar Cell

The photodiodes according to the present invention function as solar cells if no bias voltage is applied from outside. Upon irradiation of the donor-acceptor complex, the charge-separated state D⁺A⁻, and thus an internal voltage U_{D+A-}, results, which can be tapped off from outside via the electrical contacts of the donor and the acceptor. If the current circuit is closed externally, the current flow is maintained through repeated light-driven charge separation in the solar cell.

The output delivered by the solar cell is UD+A- * IET, UD+A- indicating the potential difference between the charge-separated state D+A- and the ground state DA, and IET=kET * e indicating the current intensity, with the electron transfer rate kET and the elementary charge e=1.6 *10⁻¹⁹° C.

In the bacterial reaction center of Rb. sphaeroides, upon irradiation with photons having a minimum energy of 1.37 eV, a voltage of U_{D+A-}=0.5 V is generated (R. K. Clayton & W. R. William (ed.), The Photosynthetic Bacteria, Plenum Press 1978, p. 441 ff.). The internal charge-separation rate is kET=(200 ps)⁻¹, resulting in a maximum current of 800 pA and an output of 3.2 nW per complex. However, this output can be delivered only in the case of an ideal, i.e., lossfree, contact.

If the donor of the reaction center is contacted with the natural cytochrome c, the charge transport rate in the stationary case is limited by the diffusion speed of this molecule and is about 300 ps (see above). The acceptor is contacted directly to a conductive surface via a molecular conductor such that the charge transfer rate of this contact does not determine speed. For the entire system with k_{ET}=(300 μs)⁻¹, this type of contact results in a current of 0.5 fA per complex.

A maximum of 10¹³ reaction centers per cm² may be applied on a smooth electrode. With this arrangement, a current density of 5 mA/cm² and an output density of 2.5 mW/cm² is achieved.

If rough or porous electrode surfaces are used, the packing density increases by up to a factor of 100 compared to a flat electrode. This allows higher current and power densities to be achieved accordingly. To increase the efficiency of the solar cell, light collector complexes, especially made up of bacteriochlorophylls, can be arranged—just as in the case of natural systems—around the primary donor. They increase the overall absorption cross section, transfer their excitation energy to the primary donor of the RC, and thus contribute to increasing the efficiency of the molecular solar cell.

5. Sensor

The electron transfer properties of the diode according to the present invention may be influenced, not only by light, but also by other physical quantities. If the influence is significant in an embodiment, that embodiment can be employed as a sensor for the relevant quantity. In particular, the following embodiments may be realized:

5a. Temperature Sensor

The temperature sensor is characterized by significant dependence of the diode current on temperature. A distinction may be made between two embodiments,
a) a temperature sensor based on a diode operated in forward direction and
b) a temperature sensor based on a diode operated in reverse direction.
   5aa) Temperature Sensor Based on a Diode Operated in Forward Direction

Embodiment 5aa is realized when the recombination rate is significantly temperature dependent. Such a temperature dependence is given when the recombination occurs via a thermally populated intermediate state—for example an electronically excited state, especially D* or A*. Thus, with increasing temperature, the recombination rate increases, and with it, the forward current.

An example of this type of temperature sensor is the porphyrin-quinone system described in FIG. 2c, if all substituents R are methyl groups. In this system, energetically, the state D* lies above the charge-separated state D⁺A⁻ with an enthalpy difference that, at room temperature, is on the same order as the thermal energy k_{B}T=0.025 eV (T. Haberle, dissertation, TU Munich 1995, p. 81). The recombination can thus occur, thermally activated, via the state D* and is thus strongly temperature dependent. Consequently, also the forward current of the photodiode is strongly temperature dependent.

5ab) Temperature Sensor Based on a Diode Operated in Reverse Direction Embodiment 5ab is realized when the generation rate is significantly temperature dependent. Such a dependence on temperature is given when the charge-separated state can be thermally populated upon application of a reverse voltage. Thus, with increasing temperature, the generation rate increases, and with it, the reverse current.

The porphyrin-quinone system shown in FIG. 2c is an example of this type of temperature sensor, if the substituents R at the porphyrin are methyl groups, but that at the quinone is a methoxy group. In this system, energetically, the charge-separated state D⁺A⁻ lies above the state D*, with an enthalpy difference that, at room temperature, is on the same order as the thermal energy k_{B}T=0.025 eV (T. Haberle, dissertation, TU Munich 1995, p. 81). If this system is illuminated with light of wavelength 630 nm, the excited state D* forms, from which the charge-separated state D⁺A⁻ can form through thermal activation. The generation rate is thus strongly temperature dependent, and with it, the reverse current of the molecular diode.

5b. Pressure Sensor

In general, exerting pressure on the donor-acceptor complex reduces the spacing between the donor and the acceptor, thereby increasing the interaction between them, and the recombination rate. The diode current thus increases with the pressure. A particularly strong pressure dependence of the diode current is achieved with donor-acceptor complexes in which the spacing between the donor and the acceptor is very flexible and a large relative change in spacing is associated with an increase in pressure.

Examples of the pressure sensor according to the present invention are the bridged porphyrin-quinone system shown in FIG. 3b and the bacteriochlorophyll PQQ system shown in FIG. 3c. The latter has a rather strong pressure sensitivity due to the single bridge.

5c. Acceleration Sensor

Upon acceleration of the sensor, if the donor and acceptor respectively have a large mass, a force acts upon them that can change the geometry of the donor-acceptor complex and thus the recombination rate. Particularly suitable for this is a pressure sensor of embodiment 5b, in which substances having a large mass are attached to both the donor and the acceptor.

An example of the acceleration sensor according to the present invention is the bacteriochlorophyll-PQQ system, shown in FIG. 3c, which on the one side is attached directly to an electrode—preferably with the quinone to a gold electrode—and additionally, on the other side, to a heavy molecule—preferably a fullerene (C60-molecule).

6. LED

The light-emitting diode (LED) is based on a diode described under point 2, operated in forward direction. The diode emits radiation when the state D⁺A⁻, formed through the external voltage, radiantly recombines. For this purpose, it is necessary that, from the state D⁺A⁻, an electronically excited state can be populated, especially D* or A*, that radiantly crosses over to the ground state.

An example of such a donor-acceptor complex is the porphyrin-quinone system already described under 5ab, having at the quinone a methoxy substituent, the charge-separated state D⁺A⁻ of which, energetically, lies above the excited state D* of the donor. If the diode is operated in forward direction, the external voltage causes the charge-separated state to form, which can recombine into the excited state D*. This excited state decays radiantly and, in doing so, emits light in the spectral range between 600 and 750 nm.

The diodes may also be arranged in the form of a grid in a matrix that can serve as a display element. In this way, number or letter displays or two-dimensional displays consisting of point matrices may be produced.

7. Optocoupler

The optocoupler according to the present invention consists of a combination of an LED described under point 6 and a photodiode described under point 3. The two devices are arranged side by side such that the radiation emitted from the LED preferably strikes the photodiode. They are coordinated such that the radiation emitted from the LED has sufficient energy—in terms of both the number and the frequency of photons—to address the photodiode. Such an optocoupler can be employed to transmit to its output (the photodiode) an electrical signal applied at its input (the LED), without the input and output being electrically joined together. Thus, electrical decoupling of the signals is achieved.

An example of such an optocoupler consists of the LED described in section 6, covalently joined, near the primary donor D, with the photodiode according to the present invention, consisting of the photosynthetic reaction center of Rb. sphaeroides. Upon application of a voltage to the LED, it emits light in the spectral range between 600 and 750 nm, which is absorbed by the pigments of the RC and sets the latter's primary donor into the electronically excited state D*, from which the charge-separated state D⁺A⁻ forms. The voltage forming here can be tapped off between the donor and acceptor, or between the contact spots K1 and K2 of the RC as optocoupler outputs.

8. Transistor

The molecular transistors according to the present invention comprise three redox-active substances—either one electron donor and two acceptors (NPN transistor) or one acceptor and two donors (PNP transistor). The three redox-active substances are respectively arranged in tandem such that donor and acceptor alternate. Just as in the case of semiconductor transistors, the two outer substances are referred to as emitter and collector, and the middle substance as the base.

By way of example, an NPN transistor, the emitter and collector of which respectively consist of a quinone (electron acceptor), and the base of which consists of a porphyrin (electron donor) is described below. An exemplary embodiment based on a double-bridged quinone-porphyrin-quinone system (cf. F. Pollinger, dissertation, TU Munich 1993, p. 49) is shown in FIG. 4a. The molecular NPN transistor illustrated there is based on a double-bridged quinone-porphyrin-quinone system. Both the collector C and emitter E consist of a quinone having a respective contact spot, KC and KE, and are bridged with the base B—a porphyrin having the associated contact spot KB. A symbolic illustration of this transistor is shown on the right-hand side of the image. The operating principle of such a molecular transistor is illustrated in FIG. 4b.

The NPN transistor according to the present invention acts as an electrical switch or an amplifier when the emitter is maintained at a potential φ_{E}<φ_{A/A-} (=−1.3 V in the exemplary embodiment) and the collector at φ_{C}> _{D/D+} (=0.3 V), i.e., the collector-emitter voltage U_{CE} is greater than the potential difference Δφ=φ_{D/D+}−φ_{A/A-} (=1.6 V). The transistor is switched through by applying to the base a potential (pB in the range φ_{C}>φ_{B}>φ_{D/D+} (FIG. 4b, case 1): In this wiring, the charge-separated state E⁻B⁺C forms in the transistor and recombines into the state EBC through internal electron transfer. While the electron on the emitter is supplied subsequently directly via the emitter terminal (emitter current IE), an electron can be drawn off from the base in two ways. Either the base is oxidized directly via a base current IB, or a further internal electron transfer to the collector occurs and, ultimately, restores the initial state E⁻B⁺C via a collector current IC. The amplification factor of the transistor V≡I_{E}/I_{B}=1/p follows from the probability p that the electron will be drawn off via the base rather than via the collector.

The transistor blocks when a potential φ_{B}<φ_{D/D+} is applied to the base (FIG. 4b, case 2): In this wiring, the charge-separated state E⁻B⁺C cannot form, thereby preventing an internal electron transfer and thus a current flow.

To achieve an amplification factor V that is as large as possible, the potential difference φ_{C}-φ_{B} must be chosen to be so large that the internal electron transfer from the base to the collector progresses without activation, if possible. In the case of the cited porphyrin-quinone systems, for example, activationless electron transfer occurs at a potential difference of 0.8 V. Furthermore, the transistor device can be optimized to the effect that the electron transfer via the base terminal does not function as well as, i.e. is more strongly activated or is equipped with a higher resistance than, the transfer via the collector.

9. Combination of Molecular Devices—Self-Organized Construction of Complex Circuits

Electronic circuits may be constructed by connecting multiple of the above-listed molecular devices. In particular, the following two procedures are possible:

a) Construction of the Circuit in Solution

In one embodiment, the circuit is constructed successively in solution by connecting two respective devices or modules having the coupling chemistry specific for the shared contact spot. This connecting of devices or modules is continued until a module having the desired functionality is finished. Finally, this finished module, consisting of a macromolecule or molecular conglomerate, is attached to a surface equipped with specifically modified electrodes. Here, the electrodes on the surface are respectively modified such that a specific bond can be entered into with a respective as-yet-unlinked contact spot. An example of this procedure is shown in FIG. 5 (path a).

Exemplary Description of the Method of Producing a Circuit in Solution: The construction of a simple circuit having a molecular diode and a molecular wire is described below by way of example. For this purpose, to an aqueous solution having 20% ethanol and 3×10⁻³ molar conductor—for example the thiol- and amino-terminated phenylacetylene shown in FIG. 5—is added, 10⁻³ molar, the porphyrin-quinone system shown in FIG. 2c. By adding EDC (10⁻² molar) and sulfo-NHS (10⁻² molar), after a reaction time of approximately 1-4 hours, an amide bond forms between the amino group of the molecular conductor and the carboxy group of the porphyrin-quinone system (EDC=(3-dimethylaminopropyl)-carbodiimide, sulfo-NHS=N-hydroxysulfosuccinimide). The components thus obtained are chromatographically purified by means of HPLC and can then be attached to further components or directly to the surface via their unconnected contact spots.

To contact the components on a surface, two nanoelectrodes having gold coating are produced with a distance of 1 nm. Suitable production methods are known in the semiconductor industry and are described, for example, by Porath et al. (Nature 403 (2000) 635) and Bezryadin et al. (J. Vac. Sci. Technol. B15 (1997) 411). Here, the nanoelectrodes are patterned in an SiN-layer on an oxidized silicon substrate by means of electron beam lithography, and sputtered with gold through a mask made up of silicon. The structures thus obtained are examined in the electron microscope. Here, those structures whose nanoelectrodes exhibit spacing between 0.5 and 1.5 nm are selected.

One of the two nanoelectrodes—the anode—is wetted via a nanopipette with an aqueous solution made up of 3×10⁻³ molar 3-mercapto-propionic acid and incubated for 5-60 min. After rinsing with ultrapure water, a monolayer functionalized with carboxy groups remains on the anode. When treating the anode, care must always be taken that the other nanoelectrode—the cathode—remains as clean as possible. The surface is thus prepared for contacting the above-described components. The components are pipetted in an aqueous 3×10⁻³ molar solution onto the cathode and incubated for 5-60 min. After rinsing with ultrapure water, a monolayer made up of molecular components remains on the cathode. By adding 95% trifluoroacetic acid (TFA) in dichloromethane, the Boc-protected amino group at the porphyrin is deprotected within 10 min. After a further rinse step, both electrodes are coated with an aqueous solution made up of EDC (10⁻² molar) and sulfo-NHS (10⁻² molar). Those molecular components on the cathode that are located closely enough (<1.5 nm) to the anode react with one of the carboxy groups on the anode within an hour. The result is a simple molecular electronic circuit having two nanoelectrodes that are connected with (at least) one molecular diode via molecular wires.

b) Construction of the Circuit on the Surface

In another embodiment, the circuit is successively applied on a surface. For this purpose, a device is first connected with a conductive surface, and successive further devices or modules are added to this surface structure. An example of this procedure is shown in FIG. 5 (path b).

10. Example of a Circuit—An Inverter

FIG. 6 shows a molecular inverter having macroscopic terminals, constructed of a molecular transistor 10, a molecular resistor 20, a connector 30, and a chip 100 having four strip conductors 110.

The strip conductors consist of gold that is vapor deposited through a patterning mask onto a substrate (glass or plastic). They possess, at one end, microcontacts 111, and at the other end, macroscopic plug or solder contacts 112, respectively made up of bare gold, while the lines between them are electrically insulated by a coating (made up of plastic, lacquer, or long-chain alkanethiols). They are referred to as G (ground), S (supply), I (input), and O (output), depending on their electronic function. The four microelectrodes are arranged in a quadrangle such that their vertices are a maximum of 10 nm apart, and I and O, and G and S respectively are opposite. They are coated with thiol-modified oligonucleotides 90, consisting of 5 to 30—in the exemplary embodiment 12—nucleotides of varying sequence.

The above-described double-bridged porphyrin-quinone system, for example, is employed as the transistor 10. It is equipped with oligonucleotides of equal length at all three contact spots. Here, the sequence SI at the base contact is complementary to the sequence SI at the microcontact of strip conductor I, and the sequence SG at the emitter contact is complementary to the sequence SG at the microcontact of strip conductor G.

The molecular resistor 20 consists of an oligonucleotide comprising a central double-stranded section made up of at least 12—in the exemplary embodiment 24—base pairs and, at both ends, a single-stranded section of the same length as the contact spots of the other devices (contact spots having the sequences SR and SS). The sequence SS at one end of the resistor is complementary to the sequence SS at the microcontact of the strip conductor S (supply).

To realize the node between the collector contact of the transistor, the resistor, and the output microcontact, a connector 30 comprising a tris-oligonucleotide (Scheffler M., et al. Angew. Chem. Int. Ed., Nov. 15, 1999, 38(22) p. 3311-3315) is employed. The latter consists of three oligonucleotides of the same length as the contact spots of the other devices, which are linked together at the 3′-end with a trifunctional linker. The tris-oligonucleotide used has the property that the sequence of an oligonucleotide SC is complementary to the sequence SC of the collector contact of the transistor, a second sequence SR is complementary to the sequence SR of the resistor, and the third sequence SO is complementary to the sequence SO of the oligonucleotide applied on the microcontact of the strip conductor O (output).

All sequences are chosen such that only those explicitly described above as complementary hybridize together. This allows a self-organizing system to be obtained that, when all of the cited substances are added to the four oligonucleotide-coated microelectrodes, reacts together such that the desired circuit forms.

The circuit is connected via the macroscopic contacts. At the contact S is applied the supply voltage Vs=+2 V opposite the terminal G. Overall, this allows the achievement that a voltage at the input terminal I is output inverted at the output terminal O, i.e. especially that a voltage increase from 0 V to 2 V at contact I entails a reduction of the output voltage from 1-2 V to 0-1 V.

1. A molecular electronic device for constructing nanoelectronic circuits, having a redox-active moiety having an electron donor (D) and an electron acceptor (A), the electron donor and the electron acceptor (A) having a respective contact spot (K1, K2) for forming connections with other devices, and the contact spots (K 1, K2) facilitating charge transport to the device and away from the device,
wherein the respective contact spot (K 1, K2) of electron donor (D) and electron acceptor (A) is a permanent contact spot for mediating the charge transport across a permanent chemical bond, the contact spot respectively comprising one of the binding partners of the chemical bond-. and wherein the permanent contact spots are adapted to forming a nucleic acid interaction a stable interaction between proteins, or an antigen-antibody interaction.

2. A molecular electronic device for constructing nanoelectronic circuits, having a redox-active moiety having an electron donor (D) and an electron acceptor (A), the electron donor (D) and the electron acceptor (A) having a respective contact spot (K1, K2) for forming connections with other devices, and the contact spots (K1, K2) facilitating charge transport to the device and away from the device,
wherein a first one of the contact spots (FIG. 3a: K2) of electron donor (D) and electron acceptor (A) is a permanent contact spot for mediating the charge transport across a permanent chemical bond, the first contact spot comprising one of the binding partners of the chemical bond, and wherein a second one of the contact spots (FIG. 3a: K1) of electron donor (D) and electron acceptor (A) is a temporary contact spot for mediating the charge transport without permanently attaching a substance to the contact spot.

3. The device according to claim 2, wherein the temporary contact spot (FIG. 3a: K1) is adapted to labile interactions between proteins or as a docking spot for redox-active substances.

4. The device according to claim 2, wherein the permanent contact spot or the permanent contact spots are adapted to forming a covalent bond or a permanent ligate-ligand interaction, especially a nucleic acid interaction, a stable interaction between proteins, an antigen-antibody interaction, or an ion-ligand interaction.

5. The device according to claim 1 or 2, wherein the redox-active moiety additionally comprises one or more macromolecules, especially further electron-donor and electron-acceptor molecules.

6. The device according to claim 1 or 2, wherein the redox-active moiety is the native or modified reaction center of photosynthesizing organisms, especially the native or modified reaction center of photosynthesizing bacteria.

7. The device according to claim 1 or 2, wherein the electron donor (D) and electron acceptor (A) are part of a donor-acceptor complex, especially a pigment-protein complex, of the reaction center of Rhodopseudomonas viridis, of the reaction center of Rhodobacter sphaeroides, of the reaction center of thermophilic bacteria, or of Chloroflexus aurantiacus.

8. The device according to claim 1 or 2, wherein the electron donor (D) and/or the electron acceptor (A) are dyes, especially flavins, (metallo)porphyrins, (metallo)chlorophylls, or (metallo)bacteriochlorophylls, or derivatives thereof.

9. The device according to claim 1 or 2, wherein the electron donor (D) and/or the electron acceptor (A) are nicotinamides or quinones, especially pyrrolo-quinoline quinones (PQQ), 1,2-benzoquinones, 1,4-benzoquinones, 1,2-naphtoquinones, 1,4-naphtoquinones, or 9,10-anthraquinones, or derivatives thereof.

10. The device according to claim 1 or 2, wherein the electron donor (D) and/or the electron acceptor (A) are charge-transfer complexes.

11. The device according to claim 10, wherein the charge-transfer complex is a transition metal complex, especially an Ru(II), a Cr(III), an Fe(II), an Os(II), or a Co(II) complex.

12. The device according to claim 1 or 2, wherein the electron donor (D) is selected from the group fullerene, especially C60, p-doped fullerene, and carotenoid.

13. The device according to claim 1 or 2, wherein the electron acceptor (A) is selected from the group fullerene, especially C60, n-doped fullerene, and stilbene.

14. The device according to claim 1 or 2, wherein the binding partner of the chemical bond of the permanent contact spot(s) is selected from the group consisting of amino groups and groups that can be specifically linked therewith, especially carboxy and hydroxyl groups, activated esters, especially succinimidyl esters, isothiocyanates, sulfonyl chlorides, and aldhehydes—thiol groups and groups that can be specifically linked therewith, especially alkyl halides, haloacetamides, maleimides, aziridines, and symmetrical disulfides—hydroxyl groups and groups that can be specifically linked therewith, especially acyl azides, isocyanates, acyl nitriles, and acyl chlorides—aldehydes, ketones, and groups that can be specifically linked therewith—especially hydrazines and aromatic amines.

15. The device according to claim 14, wherein at least one of the binding partners of the chemical bond is provided with a protective group to prevent the forming of a connection.

16. The device according to claim 1 or 2, wherein the binding partner of the chemical bond of the permanent contact spot(s) is a single-stranded nucleic acid oligomer having a specific sequence, preferably DNA, RNA, or PNA oligonucleotide consisting of 5 to 30 nucleotides.

17. The device according to claim 1 or 2, wherein the binding partner of the chemical bond of the permanent contact spot(s) is a photoactivatable crosslinker, such as aryl azide or a benzophenone derivative.

18. The device according to claim 1 or 2, the surface of which, with the exception of the contact spots, is electrically insulating.

19. The device according to claim 18, on the surface of which, with the exception of the contact spots, electrically insulating molecular moieties are arranged, preferably molecular moieties selected from the group of peptides, proteins, and cyclodextrins.

20. The device according to claim 1 or 2, wherein a charge transfer between the electron donor (D) and the electron acceptor (A) is variable through external influences, especially through electromagnetic radiation, temperature, static electric or magnetic fields, pressure, acceleration, or a chemical environment.

21. The device according to claim 1 or 2, that includes, in addition to the electron donor (D) and the electron acceptor (A), at least a further redox-active substance, the further redox-active substance having a contact spot formed as a permanent or temporary contact spot for forming a connection with other devices.

22. The device according to claim 21, wherein the further redox-active substance is arranged such that its electrical potential influences the charge transfer between the electron donor (D) and the electron acceptor (A), especially wherein the charge-carrier transfer rate increases the higher the potential of the further redox-active substance lies, or wherein the charge-carrier transfer rate decreases the higher the potential of the further redox-active substance lies.

23. A molecular electronic module comprising two or more devices (10,20,30) according to claim 1 or 2, connected via contact spots (SC, SC, SR, SR).

24. The module according to claim 23, wherein part (SC, SC, SR, SR) of the permanent contact spots (SI,SG,SC, SC,SO,SR, SR,SS) of the devices carries corresponding binding partners, and at least part of the devices are joined together through a chemical reaction between corresponding binding partners.

25. The module according to claim 23, wherein at least part of the devices are electrically connected via linear molecules of defined conductivity arranged between their contact spots and provided with permanent contact spots at both ends.

26. The module according to claim 25, wherein the linear binding molecules are selected from the group consisting of linear, unsaturated hydrocarbons, especially polyacetylenes (CH)ₓ, carbynes Cₓ, sulfur-nitrogen polymers (SN)ₓ, polypyrroles, and phenylacetylenes (oligo-phenylethynyls), double-stranded nucleic acid oligomers, especially DNA, RNA, or PNA, biological nerve cells, carbon nanotubes, silicon nanowires, conductive organic crystals, such as fluoranthene hexafluorophoshate and perylene hexafluorophoshate, and other radical cation salts of the arenes.

27. The module according to claim 25, wherein at least one of the linear binding molecules consists substantially of unsaturated hydrocarbons, and the electrical resistance of which is increased by incorporating individual saturated carbon atoms.

28. The module according to claim 25, wherein at least one of the linear binding molecules consists substantially of double-stranded nucleic acid oligomers, and the electrical resistance of which is increased by incorporating base mismatches or sections of single-stranded nucleic acid oligomers.

29. The module according to claim 25, wherein at least one of the linear binding molecules is formed by a doped carbon nanotube, the conductivity of which is changed by incorporating foreign atoms.

30. The module according to claim 23, that electrically forms an AND, OR, NAND, NOR, or EXOR gate, a memory element, especially an ROM or SRAM, an amplifier, or a sensor.

31. An electronic circuit having at least one molecular device according to claim 1 or 2, or a molecular electronic module according to claim 23,
wherein at least one device (10, 20, 30) is attached to an electrically conducting surface (111), especially through covalent attachment or specific adsorption.

32. A method for producing an electronic circuit, wherein in solution
at least one first component part is added, wherein a component part comprises
a device according to claim 1 or 2 or a molecular electronic device with a redox-active moiety having an electron donor (D) and an electron acceptor (A), the electron donor and the electron acceptor (A) having a respective contact spot (K1, K2) for forming connections with other devices, and the contact spots (K1, K2) facilitating charge transport to the device and away from the device, wherein the respective contact spot (K1 K2) of electron donor (D) and electron acceptor (A) is a permanent contact spot for mediating the charge transport across a permanent chemical bond, the contact spot respectively comprising one of the binding partners of the chemical bond,
a molecular electronic module according to claim 23, or
a conductive linear connection molecule,
at least one further component part is added,
the first and the further component part having a respective permanent contact spot with corresponding binding partners, such that the first and the further component part connect in the solution at the corresponding contact spots,
the step of adding further components part is repeated,
the further component part and one of the already connected component parts having a respective permanent contact spot with corresponding binding partners, such that the component parts connect in the solution at the corresponding contact spots until a number of predetermined component parts is connected, and
the connected component parts are applied to a conductive surface.

33. A method for producing an electronic circuit, wherein
a conductive surface is provided, and in solution
at least one first component part is added and connected to the conductive surface,
at least one further component part is added,
the first and the further component part having a respective permanent contact spot with mutually assigned binding partners, such that the first and the further component part connect in the solution at the corresponding contact spots,
the step of adding further component parts is repeated,
the further component part and one of the already connected component parts having a respective permanent contact spot with corresponding binding partners, such that the component parts connect in the solution at the corresponding contact spots, until a number of predetermined component parts is connected.

34. The method for producing an electronic circuit according to claim 32, wherein, prior to a step of adding a further component part, a protective group attached to a permanent contact spot of a component part in the solution is deprotected, especially removed.

35. The method for producing an electronic circuit according to claim 33, wherein, prior to a step of adding a further component part, a protective group attached to a permanent contact spot of a component part connected to the surface is deprotected, especially removed.

36. An electronic circuit obtainable by the method of claims 32 or 33.
